(19) United States
(12) Patent Application Publication
(10) Pub. No.: US 2025/0132244 A1
(43) Pub. Date: Apr. 24, 2025

(54) INTEGRATED CIRCUIT WITH TUNABLE CAPACITOR ARRAY

(71) Applicant: Apple Inc., Cupertino, CA (US)

(72) Inventors: Bo YU, San Diego, CA (US); Haitao Cheng, San Jose, CA (US); Zhongning Liu, San Diego, CA (US); Zhang Jin, San Diego, CA (US)

(73) Assignee: Apple Inc., Cupertino, CA (US)

(21) Appl. No.: 18/616,727

(22) Filed: Mar. 26, 2024

Related U.S. Application Data
(60) Provisional application No. 63/592,023, filed on Oct. 20, 2023.

(51) Int. Cl. H01L 23/522; H01G 4/40; H01L 27/01

(52) U.S. Cl. CPC H01L 23/5223; H01G 4/40; H01L 23/5227; H10D 1/20; H10D 86/85

(57) ABSTRACT

The present disclosure describes a semiconductor structure that is resistant to induced eddy currents. The semiconductor device includes a substrate, a device layer having electronic devices on the substrate, and a metallization layer above the device layer. The first metallization layer includes first and second terminal traces, a switch, and capacitors. A first terminal of a capacitor of the capacitors is coupled to the first terminal trace via the switch. A second terminal of the capacitor is coupled to the second terminal trace. The first and second terminal traces are disposed along the same side of the capacitors.

### CROSS-REFERENCE TO RELATED APPLICATION

This application claims the benefit of U.S. Application No. 63/592,023, filed on Oct. 20, 2023, which is incorporated by reference herein in its entirety.

### FIELD

This disclosure relates to a tunable capacitor array and inductors, more particularly, to a tunable capacitor structure in a back end of line of an integrated circuit.

### BACKGROUND

To implement integrated circuits with higher storage capacity, faster processing systems, higher performance, and lower costs, the semiconductor industry continues to scale down the dimensions of circuit elements, such as active devices (e.g., field-effect transistors) and passive devices (e.g., capacitors, inductors, and resistors). As the number of circuit elements increases, implementation of these circuit elements becomes increasingly more complex.

### SUMMARY

Embodiments of the present disclosure include a semiconductor device having a substrate, a device layer on the substrate, and a metallization layer above the device layer. The device layer includes electronic devices. The metallization layer includes a capacitor structure. The capacitor structure includes first and second terminal traces, a switch, and capacitors. A first terminal of a capacitor of the capacitors is coupled to the first terminal trace via the switch. A second terminal of the capacitor is coupled to the second terminal trace. The first and second terminal traces are disposed along the same side of the capacitors.

Embodiments of the present disclosure include a semiconductor structure having a substrate, a device layer, and a metallization layer above the device layer. The device layer includes electronic devices. The metallization layer includes a capacitor structure. The capacitor structure includes first and second terminal traces, a switch, and capacitors. The second terminal trace is substantially parallel to the first terminal trace. A first capacitor of the capacitors has a first terminal coupled to the first terminal trace via the switch and a second terminal coupled to the second terminal trace. A second capacitor of the capacitors is coupled to the first and second terminal traces. The first and second terminal traces are disposed between the first capacitor and the second capacitor.

Embodiments of the present disclosure include a method for fabricating a semiconductor device. The method includes forming, on a substrate, a device layer that includes electronic devices. The method also includes forming, in a metallization layer above the device layer, a capacitor structure that includes a switch, a first terminal trace, a second terminal trace, and capacitors. The forming of the capacitor structure includes coupling a first terminal of a capacitor of the capacitors to a first end of the switch. The forming of the capacitor structure also includes coupling a second end of the switch to the first terminal trace. The forming of the capacitor structure also includes coupling a second terminal of the capacitor to the second interconnect structure. The forming of the capacitor structure also includes routing the first and second terminal traces along the same side of the capacitors.

### BRIEF DESCRIPTION OF THE DRAWINGS

Embodiments of the present disclosure are best understood from the following detailed description when read with the accompanying figures. It is noted that, according to the standard practice in the industry, various features are not drawn to scale. Features of the present disclosure can be illustrated having larger and/or smaller dimensions for clarity of discussion.

FIG. 1 shows an illustration of a cross-sectional view of a portion of a semiconductor device, according to some embodiments.

FIG. 2 shows an illustration of a circuit representation of a capacitor structure, according to some embodiments.

FIG. 3 shows an illustration of a layout representation corresponding to the circuit representation of the capacitor structure in FIG. 2, according to some embodiments.

FIG. 4 shows an illustration of a circuit representation of a capacitor structure, according to some embodiments.

FIG. 5 shows an illustration of a circuit representation of a capacitor structure, according to some embodiments.

FIG. 6 shows an illustration of a cross-sectional view of a portion of a semiconductor device, according to some embodiments.

FIG. 7 shows an illustration of a circuit representation of the capacitor structure of FIG. 2 in the vicinity of an inductor, according to some embodiments.

FIG. 8 shows an illustration of a layout representation corresponding to the circuit representation of the capacitor structure and inductor of FIG. 7, according to some embodiments.

FIG. 9 shows an illustration of a circuit representation of the capacitor structure of FIG. 4 in the vicinity of an inductor, according to some embodiments.

FIG. 10 shows an illustration of a circuit representation of the capacitor structure of FIG. 5 in the vicinity of an inductor, according to some embodiments.

FIG. 11 shows a flow chart of a method for fabricating a semiconductor device, according to some embodiments.

FIG. 12 shows a cross-sectional view of a portion of a semiconductor device at a given stage in the operations of the method of FIG. 11, according to some embodiments.

FIG. 13 shows a cross-sectional view of a portion of the semiconductor device at another stage in the operations of the method of FIG. 11, according to some embodiments.

FIG. 14 shows a cross-sectional view of a portion of the semiconductor device at a further stage in the operations of the method of FIG. 11, according to some embodiments.

FIG. 15 shows an illustration of exemplary systems or devices that can include the disclosed embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides different embodiments, or examples, for implementing different features of the provided subject matter. Specific examples of components and arrangements are described below to simplify the present disclosure. These are merely examples and are not intended to be limiting. The present disclosure can make use of reoccurring reference numerals and/or letters in the various examples. This repetition is for the purpose of simplicity and clarity and, unless indicated otherwise, does not in itself indicate a limiting relationship between the various embodiments and/or configurations discussed.

It is noted that references in the specification to “one embodiment,” “an embodiment,” “an example embodiment,” “exemplary,” and the like, indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

In some embodiments, the terms “about” and “substantially” can indicate a value of a given quantity that varies within 20% of the value (e.g., +1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

In the description of at least some embodiments herein, enumerative adjectives (e.g., “first,” “second,” “third,” “primary,” “secondary,” or the like) can be used to distinguishing like elements without establishing an order, hierarchy, quantity, or permanent numeric assignment (unless otherwise noted). In some embodiments, the terms “first power source” and “second power source” can be used in a manner analogous to “i^{th} power source” and “j^{th} power source” so as to facilitate identification of two or more power sources without specifying a particular order, hierarchy, quantity, or immutable numeric correspondence.

It is to be understood that the phraseology or terminology herein is for the purpose of description and not of limitation, such that the terminology or phraseology of the present specification is to be interpreted by those skilled in relevant art(s) in light of the teachings herein.

The following disclosure describes embodiments directed to reducing eddy currents in capacitor circuits in the proximity of an inductor that operates at a high frequency.

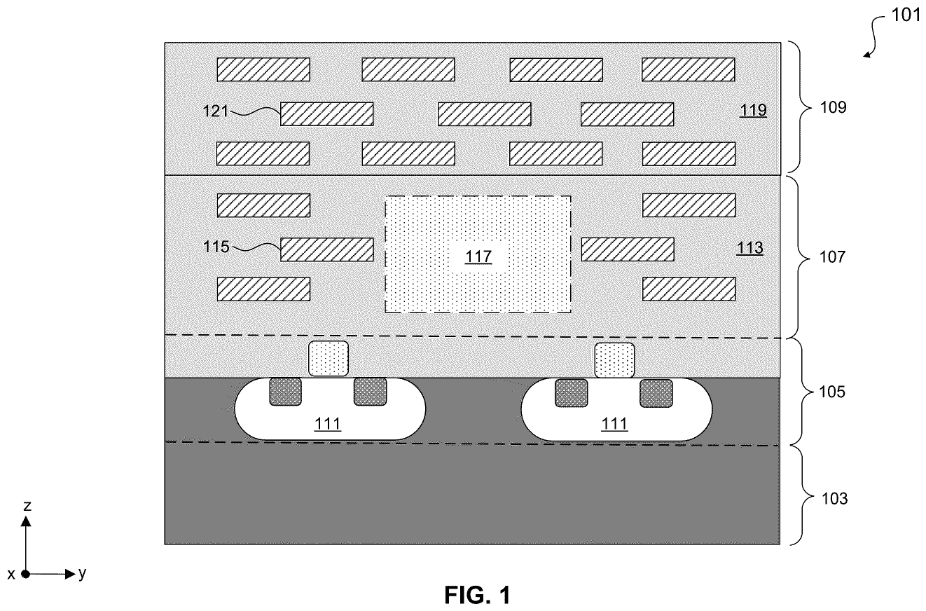

FIG. 1 shows an illustration of a cross-sectional view of a portion of a semiconductor device 101, according to some embodiments. In some embodiments, semiconductor device 101 includes layers of materials, including semiconductor materials. Semiconductor device 101 can also be referred to as a semiconductor structure 101 in reference to the layered structures and integrated circuit structures therein. Semiconductor device 101 includes a substrate 103, a device layer 105, a first metallization layer 107, and a second metallization layer 109. Second metallization layer 109 is disposed above first metallization layer 107. First metallization layer 107 is disposed above device layer 105. Device layer 105 is disposed substrate 103. First metallization layer 107 and second metallization layer 109 can be part of a back end of line (BEOL) region.

In some embodiments, substrate 103 can include a semiconductor material, such as crystalline silicon (Si). In some embodiments, substrate 103 can include (i) an elementary semiconductor (e.g., germanium), a compound (e.g., silicon carbide, silicon arsenide, gallium arsenide, gallium phosphide, and/or a III-V semiconductor material), an alloy semiconductor (e.g., silicon germanium, silicon germanium carbide, germanium tin, and/or aluminum gallium arsenide), a semiconductor-on-insulator (e.g., silicon-on-insulator (SOI), silicon germanium-on insulator, germanium-on-insulator), or a combination thereof. In some embodiments, substrate 103 can include an electrically non-conductive material, such as glass and a sapphire wafer. In some embodiments, substrate 103 can be doped to a desired dopant level using a suitable dopant (e.g., p-type substrate or n-type substrate). In some embodiments, substrate 103 can include a ceramic material.

In some embodiments, device layer 105 can include one or more electronic devices 111 implemented within and/or on substrate 103. One or more electronic devices 111 can include one or more of transistors, resistors, capacitors, and inductors. First metallization layer 107 can include interconnect structures 115 disposed in a dielectric structure 113. Second metallization layer 109 can include interconnect structures 121 disposed in a dielectric structure 119. Interconnect structures 115 and 121 can be made of a suitable metal (e.g., copper, aluminum, chromium, tungsten) for electrically connecting to one or more electronic devices 111, as well as other circuit elements present in semiconductor device 101. First metallization layer 107 also includes a capacitor region 117, which can include one or more capacitor structures. The one or more capacitor structures can function to transmit and adjust high frequency signals (e.g., adjust a phase of a high frequency signal), according to some embodiments.

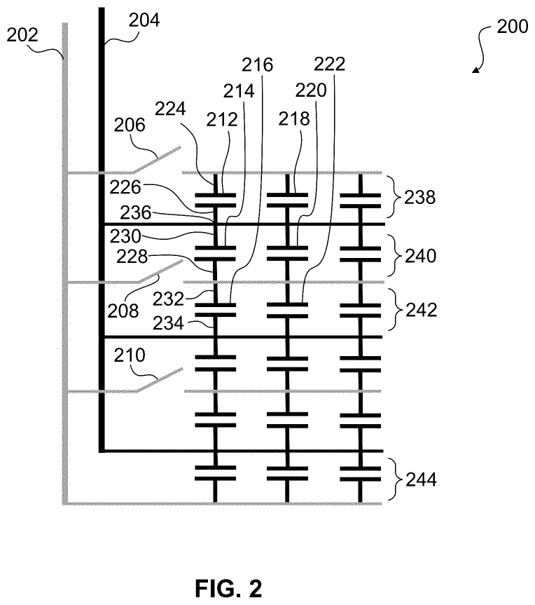

FIG. 2 shows an illustration of a circuit representation of a capacitor structure 200, according to some embodiments. Capacitor structure 200 can be implemented in capacitor region 117 of semiconductor device 101 of FIG. 1. In some embodiments, capacitor structure 200 includes capacitors, a first terminal trace 202, and a second terminal trace 204, a first switch 206, a second switch 208, and a third switch 210. For description and illustration purposes, first capacitor 212, second capacitor 214, third capacitor 216, fourth capacitor 218, fifth capacitor 220, and sixth capacitor 222 of the capacitors are assigned reference labels. Unless otherwise noted, the structures and functions of unlabeled capacitors are similar to the description of the labeled capacitors. Furthermore, in some embodiments, capacitor structure 200 can be implemented with more or fewer capacitors, more or fewer rows/columns of capacitors, more or fewer capacitors in each row/column of capacitors, and/or more or fewer switches. Capacitor structure 200 can be implemented using metal-oxide-metal (MOM) capacitors, metal-insulator-metal (MIM) capacitors, metal-oxide-semiconductor (MOS) capacitors, or any combinations thereof.

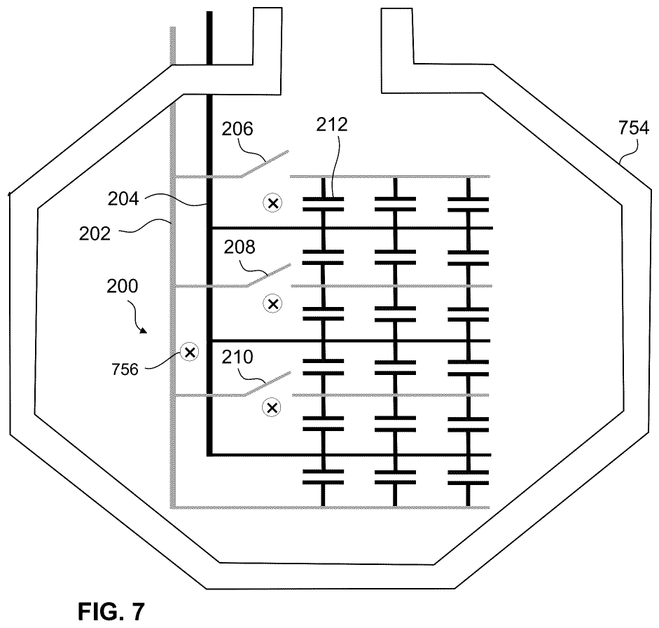

In some embodiments, the capacitors are coupled to first terminal trace 202 and second terminal trace 204. First terminal trace 202 and second terminal trace 204 can be coupled to corresponding ones of interconnect structures 115 of FIG. 1. Electrical signals can be transmitted to and from capacitor structure 200 via interconnect structures 115 of FIG. 1 and first terminal trace 202 and second terminal trace 204. As will be described below in reference to FIG. 7, in some embodiments, oscillating electromagnetic fields can induce eddy currents in a capacitor circuit. Therefore, to mitigate the eddy currents, first terminal trace 202 and second terminal trace 204 can be disposed along the same side of the capacitors. The arrangement allows for first terminal trace 202 and second terminal trace 204 to be disposed proximal to one another, thereby reducing the area of magnetic flux between first terminal trace 202 and second terminal trace 204 and thereby mitigating the formation of eddy currents in the presence of an oscillating electromagnetic signal.

Referring to FIG. 2, in some embodiments, each of the capacitors can have a first terminal and a second terminal (e.g., positive terminal and negative terminal). For ease of description and unless otherwise noted, first terminals of capacitors can be coupled to first terminal trace 202 and second terminals of capacitors can be coupled to second terminal trace 204. First capacitor 212 includes a first terminal 224 and a second terminal 226. Second capacitor 212 includes a first terminal 228 and a second terminal 230. Third capacitor 216 includes a first terminal 232 and a second terminal 234.

In some embodiments, first terminal 224 of first capacitor 212 is coupled to first terminal trace 202 via first switch 206. That is, first terminal 224 of first capacitor 212 is coupled to a first end of first switch 206 and a second end of first switch 206 is coupled to first terminal trace 202. Second terminal 226 of first capacitor 212 is coupled to second terminal trace 204. First terminal 228 of second capacitor 214 is coupled to first terminal trace 202 via second switch 208. That is, first terminal 228 of second capacitor 214 is coupled to a first end of second switch 208 and a second end of second switch 208 is coupled to first terminal trace 202. Second terminal 230 of second capacitor 214 is coupled to second terminal trace 204. It is noted that second terminal 226 of first capacitor 212 and second terminal 230 of second capacitor 214 are coupled to node 236—e.g., the same node. First terminal 232 of third capacitor 216 is coupled to first terminal trace 202 via third switch 210. That is, first terminal 232 of third capacitor 216 is coupled to a first end of third switch 210 and a second end of third switch 210 is coupled to first terminal trace 202. Second terminal 234 of third capacitor 216 is coupled to second terminal trace 204.

In some embodiments, a capacitance value of capacitor structure 200 is adjustable by adjusting first switch 206, second switch 208, and/or third switch 210 to include or exclude capacitors in the overall circuit. First switch 206, second switch 208, and/or third switch 210 can be adjusted independently from one another. First switch 206, second switch 208, and/or third switch 210 can be a type of switch that is suitable for integrated circuits (e.g., transistor and microelectromechanical system (MEMS)). The capacitors of capacitor structure 200 can be arranged as rows (e.g., two or more capacitors in a row). In an example, as illustrated in FIG. 2, first capacitor 212 and fourth capacitor 218 can be part of first row of capacitors 238, second capacitor 214 and fifth capacitor 220 can be part of second row of capacitors 240, and third capacitor 216 and sixth capacitor 222 can be part of third row of capacitors 242. First switch 206 can be toggled to turn open or close the connection to first row of capacitors 238. In some embodiments, a switch can operate on one or more rows of capacitors. For example, second switch 208 can be toggled to turn open or close the connection to second row of capacitors 240 and third row of capacitors 242. And some capacitor(s) or row(s) of capacitors can be characterized as having no switch so as to provide a baseline capacitance value, an example of which is reflected in a further row of capacitors 244. By providing multiple options to connect or disconnect a different number of capacitors, capacitor structure 200 allows for coarse and fine capacitance tuning.

In some embodiments, the capacitance value of each individual capacitor can be substantially the same or that one or more capacitors (or rows of capacitors) can have a capacitance value that is different from the rest of the capacitors. Some capacitor(s) or row(s) of capacitors can have a larger capacitance value (e.g., for coarse capacitance tuning). Some capacitor(s) or row(s) of capacitors can have a smaller capacitance value (e.g., for fine capacitance tuning).

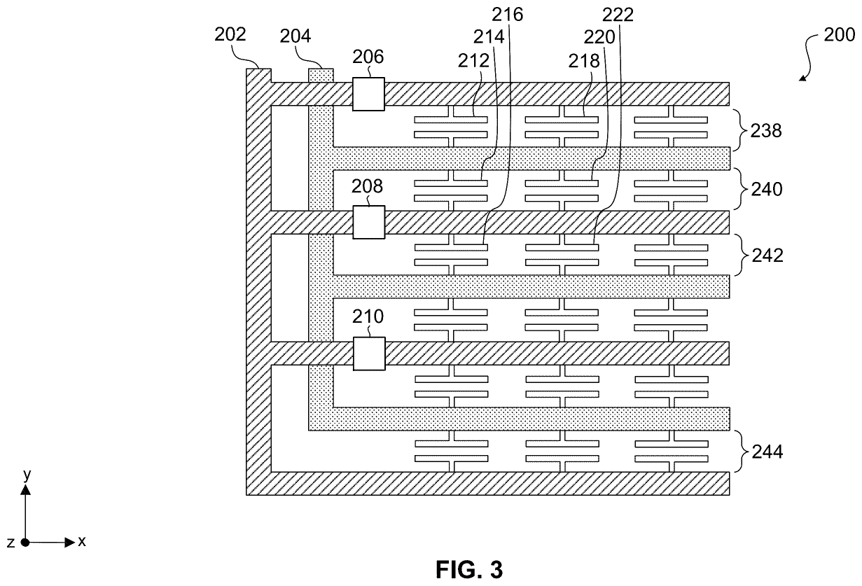

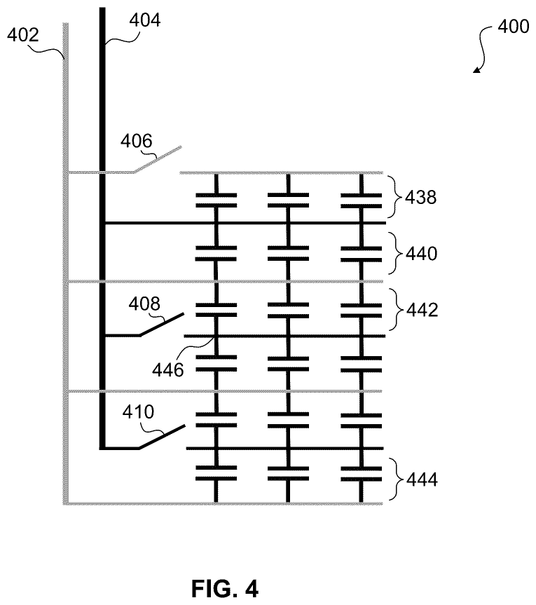

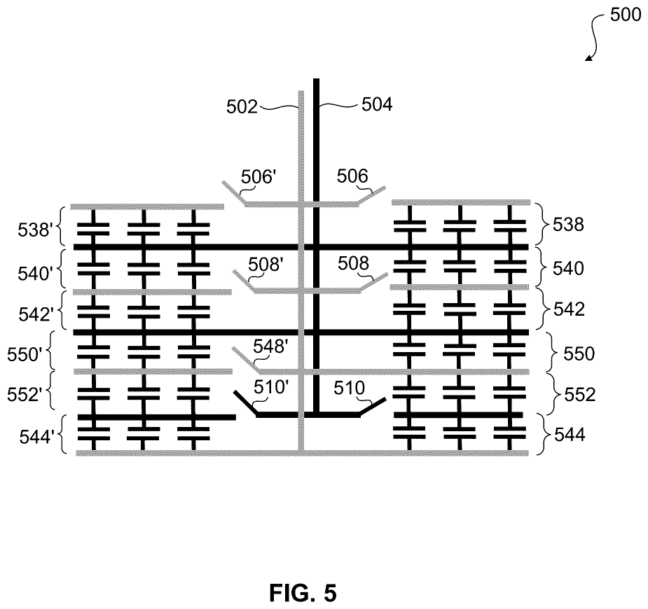

FIG. 3 shows an illustration of a layout representation corresponding to the circuit representation of capacitor structure 200 in FIG. 2, according to some embodiments. The illustrated layout is one of a number of ways to suitably design an integrated circuit layout structure in order to achieve the functions described above regarding capacitor structure 200. The trace material corresponding to first terminal trace 202 can be routed through a given height level within capacitor region 117 of FIG. 1 (e.g., in the z-direction of FIG. 1). The trace material corresponding to second terminal trace 204 can be routed through a height level (e.g., in the z-direction) that is above first terminal trace 202, within capacitor region 117 of FIG. 1, such that the material of dielectric structure 113 prevents the two terminal traces from shorting. The capacitors can be disposed at the lower of the two height levels, at the higher of the two height levels, distributed across both height levels, at a different height level from the two height levels, or distributed across multiple height levels. To couple the capacitors to the terminal traces, vias can be used to cross into the different height levels. It is to be appreciated that the layout illustrated in FIG. 3 can be adjusted to achieve the functions described in reference to other circuit-level representations disclosed herein (e.g., those of capacitor structures 400 and 500 in FIGS. 4 and 5).

In some embodiments, first terminal trace 202 and second terminal trace 204 are parallel to one another (e.g., in the y-direction). First terminal trace 202 and second terminal trace 204 are routed along a same side of the capacitors. First terminals of the capacitors in first row of capacitors 238 are coupled to first terminal trace 202 via first switch 206. Second terminals of the capacitors in first row of capacitors 238 are coupled directly to second terminal trace 204 without a switch. First terminals of the capacitors in second row of capacitors 240 are coupled to first terminal trace 202 via second switch 208. Second terminals of the capacitors in second row of capacitors 240 are coupled directly to second terminal trace 204 without a switch. Third switch 210 is coupled in a similar manner to first terminals of capacitors of another row of capacitors.

FIG. 4 shows an illustration of a circuit representation of a capacitor structure 400, according to some embodiments. It is to be appreciated that, in some embodiments, the structures and functions of individual elements of capacitor structure 400 are the same or substantially similar as the corresponding elements of FIG. 2 (e.g., corresponding elements can have reference numbers that share the two right-most numeric digits), unless otherwise noted or readily apparent from the differences between the figures. Therefore, for simplicity of description, not every element in FIG. 4 is labeled and expressly described. Elements relevant to the description of FIG. 4 have been labeled, which include a first terminal trace 402, a second terminal trace 404, a first switch 406, a second switch 408, a third switch 410, a first row of capacitors 438, a second row of capacitors 440, a third row of capacitors 442, further row of capacitors 444, and a node 446.

In some embodiments, second switch 408 and third switch 410 are coupled to second terminal trace 404 while switch 406 remains coupled to first terminal trace 402 (in contrast to FIG. 2, where first switch 206, second switch 208, and third switch 210 are connected to the same terminal trace—e.g., terminal trace 202). In view of the capacitor and switch arrangements in FIGS. 2 and 4, the position of the switches can be chosen to suit a given circuit design/function. For example, row of capacitors 444 is now controllable via third switch 410 (whereas, in FIG. 2, further row of capacitors 244 has a permanent closed connection to the circuit). Second row of capacitors 440 is not controllable via any of the switches (permanent closed connection to the circuit). If the different rows of capacitors represents different capacitance values for coarse and fine-tuning, then the choice of specific positions for the switches (or absence of one or more switches) can be used to set a baseline capacitance value for capacitor circuit 400 without having to alter the layout design of the individual capacitors, which can save space and reduce design complexity. And, whereas node 236 in FIG. 2 is coupled to second terminal trace 204 without the presence of an intervening switch, node 446 in FIG. 4 is coupled to second terminal trace 404 via second switch 408.

FIG. 5 shows an illustration of a circuit representation of a capacitor structure 500, according to some embodiments. It is to be appreciated that, in some embodiments, the structures and functions of individual elements of capacitor structure 500 are the same or substantially similar as the corresponding elements of FIGS. 2 and 4 (e.g., corresponding elements can have reference numbers that share the two right-most numeric digits), unless otherwise noted or readily apparent from the differences between the figures. Therefore, for simplicity of description, not every element in FIG. 5 is labeled and expressly described. Elements relevant to the description of FIG. 5 have been labeled, which include first terminal trace 502, second terminal trace 504, first switch 506, second switch 508, third switch 510, first row of capacitors 538, second row of capacitors 540, third row of capacitors 542, and further row of capacitors 544. Though not labeled in previous figures, the description of FIG. 5 will also reference rows of capacitors 550 and 552.

Whereas in FIGS. 2 and 4 capacitors are disposed on one side of the terminal traces (e.g., the right side), in some embodiments, capacitor structure 500 includes capacitors on both sides of the terminal traces (e.g., between the right set of capacitors and left set of capacitors).

As shown in FIG. 5, in some embodiments, capacitor structure 500 also includes a left-side arrangement of capacitors and switches, which includes switch 506′, switch 508′, switch 510′, and rows of capacitors 538′, 540′, 542′, 544′, 550′, and 552′ in addition to the capacitor arrangement on the right side of first and second terminal traces 502 and 504. First and second terminal traces 502 and 504 can be referred to as a unit pair of traces and the unit pair of traces can be disposed between the right-side and left-side capacitor arrangements (e.g., between row of capacitors 538 and row of capacitors 538′). In some embodiments, the left-side capacitor arrangement does not mirror the right-side capacitor arrangement in either structure (e.g., switch positions) or capacitance values. That is, the left-side capacitor arrangement can be designed differently than the right-side capacitor arrangement.

In contrast to corresponding elements of capacitor structures 400 of FIG. 4, in some embodiments, second switch 508 is returned to the position of switch 208 in FIG. 2 while first switch 506 and third switch 510 remain in the positions illustrated by first switch 406 and third switch 410 of FIG. 4. The various illustrations with varied switch positions further underscore the advantages of the freedom to choose a given design and layout that meets a criteria of circuit performance goals without adversely impacting integrated circuit manufacturing processes.

In some embodiments, switch 506′, switch 508′, and switch 510′ mirror the positions of first switch 506, second switch 508, and third switch 510, respectively. Rows of capacitors 552′ and 554′ are coupled to first terminal trace 502 via switch 548′, which is a configuration that is not mirrored in the right-side capacitor arrangement. This difference allows different on/off permutations on the left-side capacitor arrangement compared to the on/off permutations of the right-side capacitor arrangement, thereby providing additional functionality for fine-tuning the capacitance value of capacitor structure 500. With more choices to turn on and off different rows of capacitors, the capacitance value of capacitor structure 500 can be more finely tuned, according to some embodiments.

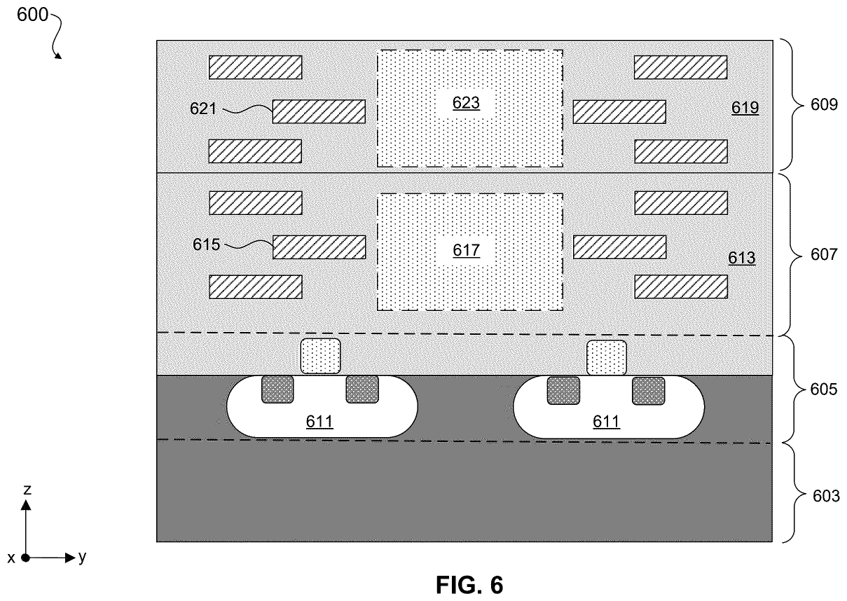

FIG. 6 shows an illustration of a cross-sectional view of a portion of a semiconductor device 601, according to some embodiments. It is to be appreciated that, in some embodiments, the structures and functions of individual elements of semiconductor structure 601 are the same or substantially similar as the corresponding elements of FIG. 1 (e.g., corresponding elements can have reference numbers that share the two right-most numeric digits), unless otherwise noted or readily apparent from the differences between the figures. The elements of FIG. 6 as they correspond to the elements of FIG. 1 are a substrate 603, a device layer 605, a first metallization layer 607, a second metallization layer 609, one or more electronic devices 611, dielectric structures 613 and 619, interconnect structures 615 and 619, and a capacitor region 617. In contrast to FIG. 1, second metallization layer 619 also includes an inductor region 623, which can include one or more inductors.

In some embodiments, capacitor region 617 can include one or more of the capacitor structure embodiments described herein (e.g., capacitor structures 200, 400, and/or 500 of FIGS. 2, 4, and 5). Inductor region 623 is proximal to, and at least partially overlaps (e.g., in the z-direction), capacitor region 617. Hence, one or more inductors in inductor region 623 can at least partially overlap capacitors in capacitor region 617. Such an arrangement is beneficial for compactness and size optimization of the integrated circuit implemented in semiconductor device 601. As discussed above, inductors can generate electromagnetic signals that can induce undesirable eddy currents in nearby circuit elements, such as those of a capacitor circuit.

FIG. 7 shows an illustration of a circuit representation of capacitor structure 200 of FIG. 2 in the vicinity of an inductor 754, according to some embodiments. In some embodiments, capacitor structure 200 can be disposed in capacitor region 617 of FIG. 6 while inductor 754 can be disposed in inductor region 617 of FIG. 6. Inductor 754 at least partially overlaps capacitor structure 200 (e.g., can overlap first capacitor 212 or more capacitors).

In some embodiments, inductor 754 can generate an oscillating electromagnetic signal having a magnetic field 756 component into the page, indicated by vector-into-page symbols (circle-crosses). One magnetic field vector symbol is illustrated between first and second terminal traces 202 and 204. By having first and second terminal traces 202 and 204 disposed parallel to one another and/or on the same side of the capacitors, the flux area through which magnetic field 756 can act on is reduced, thereby mitigating eddy currents induced by magnetic fields 756 from inductor 756. Furthermore, first, second, and third switches 206, 208, and 210 can also mitigate eddy currents. Unused capacitors in the circuit correspond to one or more switches being in the open state. Since eddy currents can form in closed loops within conductors, open switches (e.g., breaks in the circuit loop) deter eddy current formation.

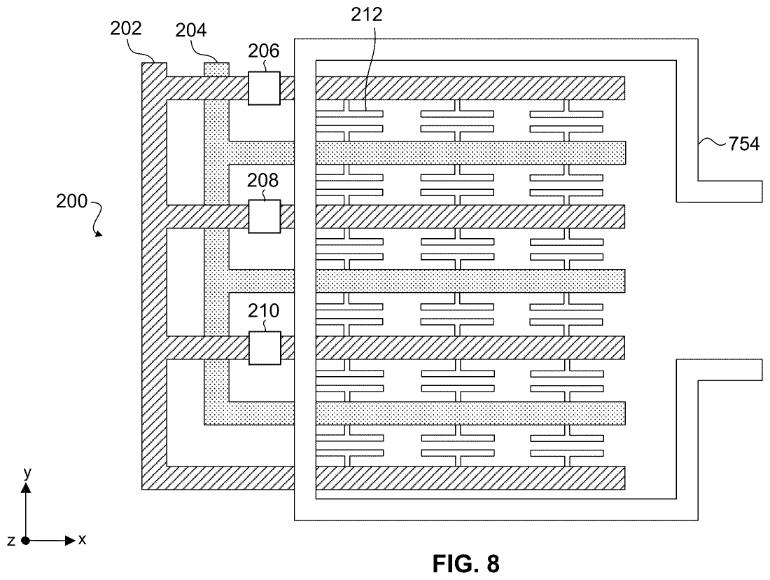

FIG. 8 shows an illustration of a layout representation corresponding to the circuit representation of capacitor structure 200 and inductor 754 in FIG. 7, according to some embodiments. The illustrated layout is one of a number of ways to suitably design an integrated circuit layout structure in order to achieve the functions described above regarding capacitor structure 200 and inductor 754. It is to be appreciated that the layout illustrated in FIG. 8 can be adjusted to achieve the functions described in reference to other circuit-level representations disclosed herein (e.g., those of capacitor structures 400 and 500 with inductor 754 in FIGS. 4, 5, and 7).

In some embodiments, the trace material corresponding to first terminal trace 202 can be routed through a given height level within capacitor region 617 of FIG. 6 (e.g., in the z-direction of FIG. 1). The trace material corresponding to second terminal trace 204 can be routed through a height level (e.g., in the z-direction) that is above first terminal trace 202, within capacitor region 617 of FIG. 6, such that the material of dielectric structure 613 prevents the two terminal traces from shorting. The capacitors can be disposed at the lower of the two height levels, at the higher of the two height levels, distributed across both height levels, at a different height level from the two height levels, or distributed across multiple height levels. To couple the capacitors to the terminal traces, vias can be used to cross into the different height levels.

In some embodiments, first terminal trace 202 and second terminal trace 204 are parallel to one another (e.g., in the y-direction). First terminal trace 202 and second terminal trace 204 are routed along a same side of the capacitors. First terminals of the capacitors in first row of capacitors 238 are coupled to first terminal trace 202 via first switch 206. Second terminals of the capacitors in first row of capacitors 238 are coupled directly to second terminal trace 204 without a switch. First terminals of the capacitors in second row of capacitors 240 are coupled to first terminal trace 202 via second switch 208. Second terminals of the capacitors in second row of capacitors 240 are coupled directly to second terminal trace 204 without a switch. Third switch 210 is coupled in a similar manner to first terminals of capacitors of another row of capacitors.

In some embodiments, inductor 754 is disposed in inductor region 623 of FIG. 6, which can overlap one or more of the capacitors in capacitor region 617 of FIG. 6. The area of inductor 754 overlaps at least first capacitor 212. FIG. 8 illustrates an example in which the area of inductor 754 fully overlaps the group of capacitors. In an integrated circuit, overlapping structures can help reduce the size and volume of the circuit, thereby reducing cost. Capacitor structures 200, 400, and 500 shown in FIGS. 2-5 and 7-10 allow for close overlap and size optimization of circuit elements while mitigating undesirable eddy currents.

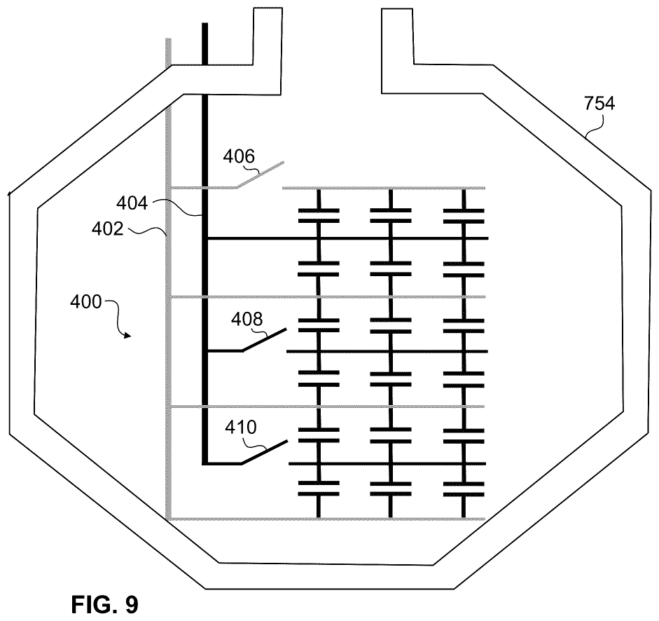

FIG. 9 shows an illustration of a circuit representation of capacitor structure 400 of FIG. 4 in the vicinity of inductor 754, according to some embodiments. In some embodiments, capacitor structure 400 can be disposed in capacitor region 617 of FIG. 6 while inductor 754 can be disposed in inductor region 617 of FIG. 6. Inductor 754 at least partially overlaps capacitor structure 400 (e.g., overlaps at least one capacitor).

In some embodiments, similar to the benefits described with respect to capacitor structure 200 in FIG. 7, capacitor structure 400 in FIG. 9 can achieve mitigation of eddy currents under the influence of magnetic fields generated by the nearby inductor 754 while using a configuration of switches that is different from the configuration of capacitor structure 200.

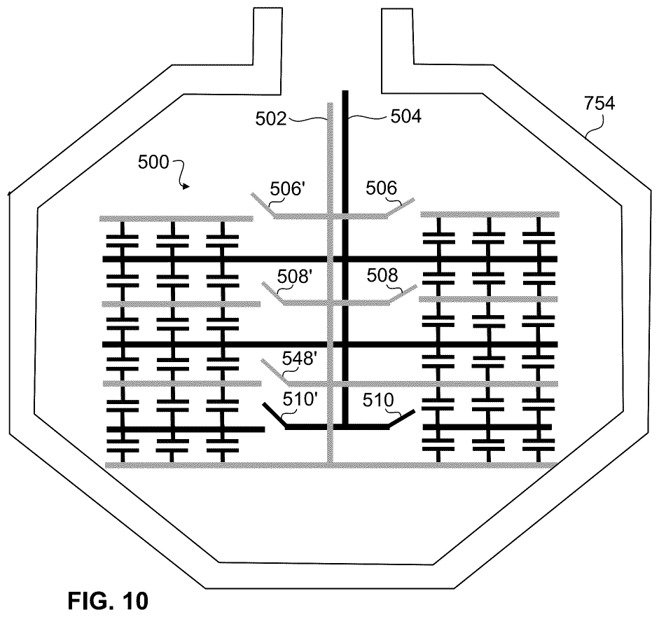

FIG. 10 shows an illustration of a circuit representation of capacitor structure 500 of FIG. 5 in the vicinity of inductor 754, according to some embodiments. In some embodiments, capacitor structure 500 can be disposed in capacitor region 617 of FIG. 6 while inductor 754 can be disposed in inductor region 617 of FIG. 6. Inductor 754 at least partially overlaps capacitor structure 500 (e.g., overlaps at least one capacitor).

In some embodiments, similar to the benefits described with respect to capacitor structures 200 and 400 in FIGS. 7 and 9, capacitor structure 500 in FIG. 10 can achieve mitigation of eddy currents under the influence of magnetic fields generated by the nearby inductor 754 while using a configuration of switches that is different from the configurations of capacitor structures 200 and 400.

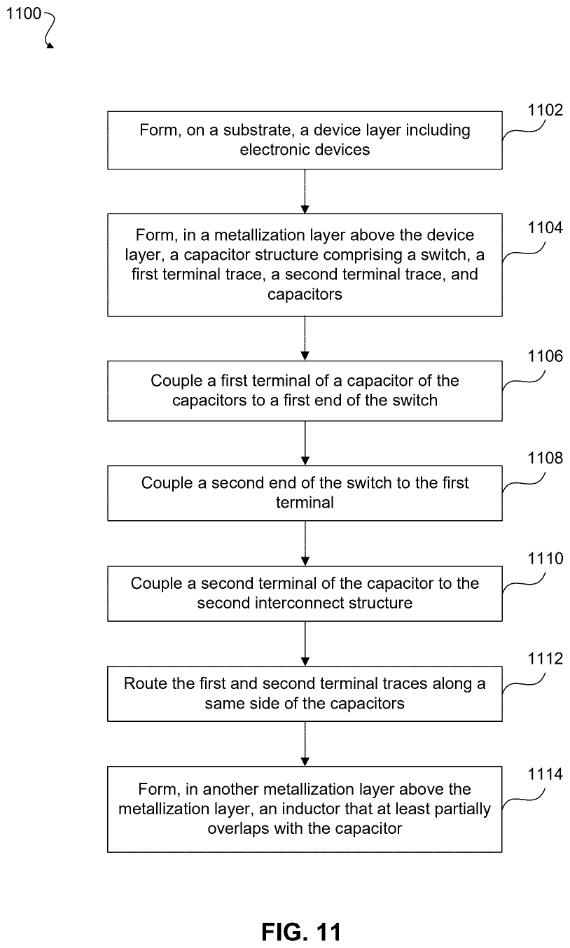

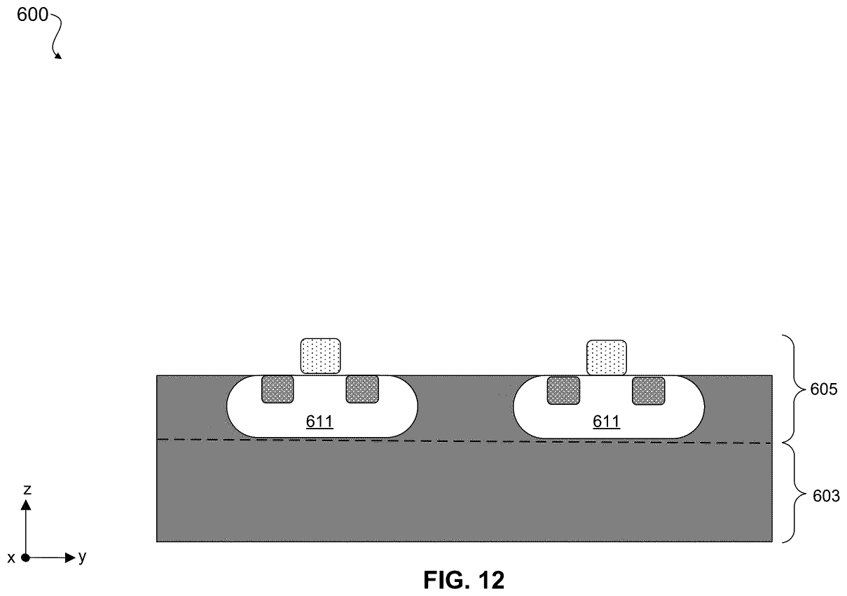

FIGS. 11-14 show illustrations of a method 1100 for fabricating semiconductor devices 101 and/or 601, according to some embodiments. FIG. 11 shows a flow chart for method 1100. FIGS. 12-14 illustrate semiconductor structure 601 at various stages of method 1100. Additional operations can be performed between various operations of method 1100 and can be omitted for clarity and ease of description. The additional operations can be provided before, during, and/or after method 1100. Moreover, it may not be needed to perform all of the operations. Additionally, some of the operations may be performed simultaneously or in a different order than shown in FIG. 11. In some embodiments, one or more other operations may be performed in addition to or in place of the presently described operations.

To aid in the description of method 1100, reference shall be made to semiconductor structure 601 of FIG. 6, as well as capacitor structures 200, 400, and 500 that appear in the various figures of the present disclosure. And while reference will be made to elements of semiconductor device 601 of FIG. 6, it is to be appreciated that method 1100 is applicable to corresponding elements of semiconductor device 100 of FIG. 1, as well as corresponding elements of capacitor structures that are not expressly referenced.

In some embodiments, at operation 1102, device layer 605 including electronic devices 611 is formed on substrate 603 as shown in FIG. 12. Electronic devices 611 can be fabricated in and/or on substrate 603. Suitable integrated circuit fabrication techniques can be used for operation 1102 (e.g., doping to create semiconductor junctions, forming gate material, and fabricating electrical contacts).

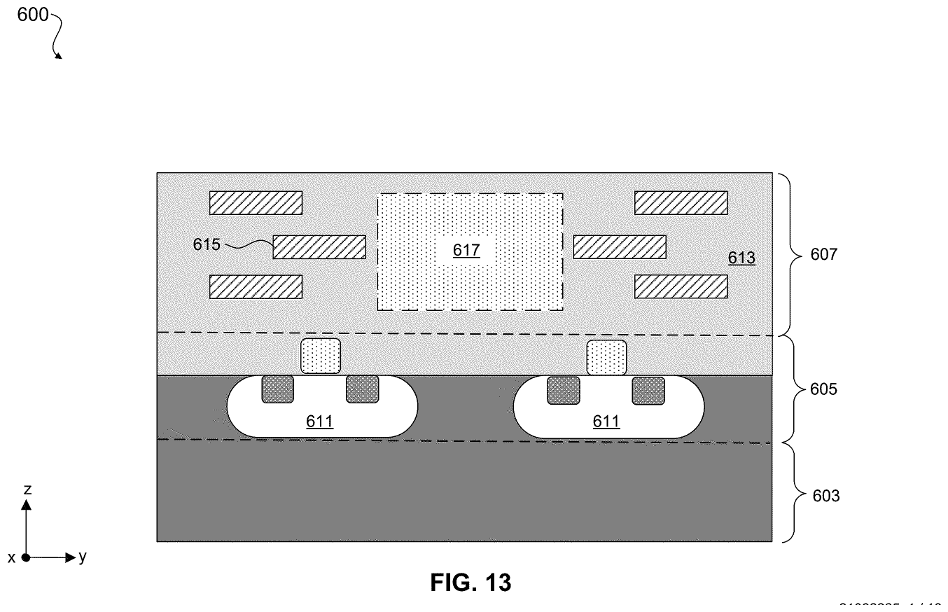

In some embodiments, at operation 1104, first metallization layer 607 is formed above device layer 605, as shown in FIG. 13. The forming at operation 1104 includes forming capacitor structures 200, 400, and/or 500 in capacitor region 617. Operation 1104 can be further subdivided into discrete operations, such as operations 1106, 1108, 1110, and 1112.

In some embodiments, at operation 1106 for forming the capacitor structure(s), first terminal 224 of first capacitor 212 is coupled to a first end of first switch 206, as shown in FIGS. 2, 3, 7, and 8.

In some embodiments, at operation 1108 for forming the capacitor structure(s), a second end of first switch 206 is coupled to first terminal trace 202, as shown in FIGS. 2, 3, 7, and 8.

In some embodiments, at operation 1110 for forming the capacitor structure(s), second terminal 226 of first capacitor 212 is coupled to second interconnect structure 204, as shown in FIGS. 2, 3, 7, and 8.

In some embodiments, at operation 1112 for forming the capacitor structure(s), as shown in FIGS. 2, 3, 7, and 8, first and second terminal traces 202 and 204 are routed along the same side of the grouped capacitors of capacitor structure 200 (e.g., in the y-direction). First and second terminal traces 202 and 204 are routed in parallel in first metallization layer 607.

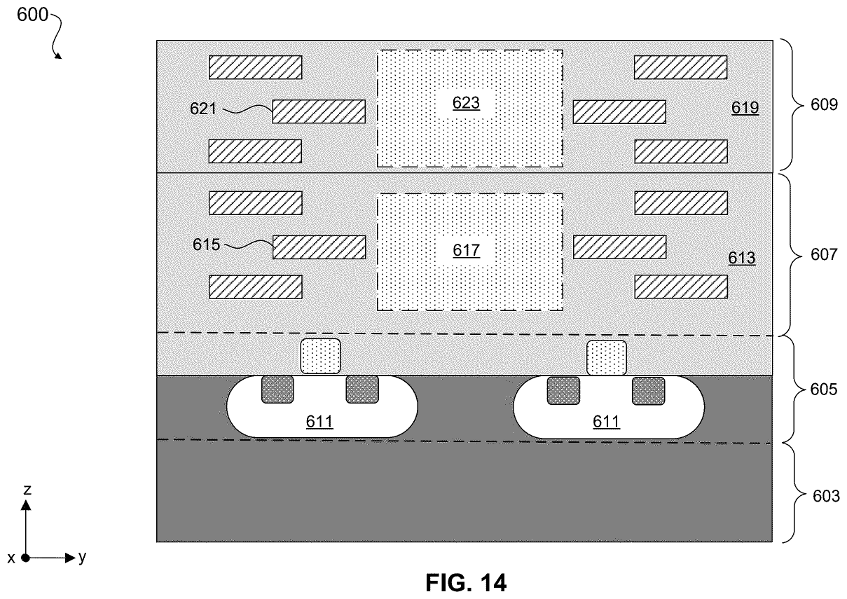

In some aspects, at operation 1114, second metallization layer 609 is formed above first metallization layer 607, as shown in FIG. 14. The forming at operation 1114 includes forming inductor 754 at inductor region 623. The forming of inductor 754 can include forming inductor 754 such that it overlaps at least one capacitor in capacitor region 617 below, as shown in FIG. 8. The area of inductor 754 overlaps at least first capacitor 212, as shown in FIG. 8. Inductor 754 can overlap two or more capacitors. The example illustrated in FIG. 8 shows inductor 754 fully overlapping the group of capacitors. In an integrated circuit, overlapping structures can help reduce the size and volume of the circuit, thereby reducing cost. Fabrication of capacitor structures 200, 400, and 500 according to method 1100 allow for close overlap and size optimization of circuit elements while mitigating undesirable eddy currents.

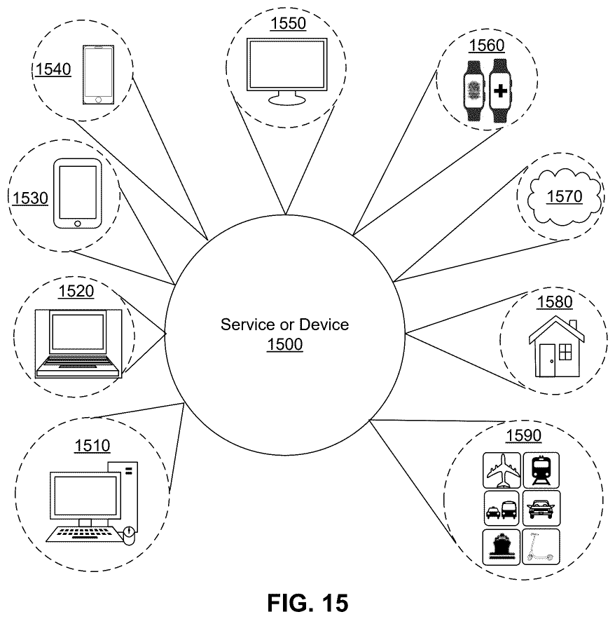

FIG. 15 shows an illustration of exemplary systems or devices that can include the disclosed embodiments. System or device 1500 can incorporate one or more of the disclosed embodiments in a wide range of areas. For example, system or device 1500 can be implemented in one or more of a desktop computer 1510, a laptop computer 1520, a tablet computer 1530, a cellular or mobile phone 1540, and a television 1550 (or a set-top box in communication with a television).

Also, system or device 1500 can be implemented in a wearable device 1560, such as a smartwatch or a health-monitoring device. In some embodiments, the smartwatch can have different functions, such as access to email, cellular service, and calendar functions. Wearable device 1560 can also perform health-monitoring functions, such as monitoring a user's vital signs and performing epidemiological functions (e.g., contact tracing and providing communication to an emergency medical service). Wearable device 1560 can be worn on a user's neck, implantable in user's body, glasses or a helmet designed to provide computer-generated reality experiences (e.g., augmented and/or virtual reality), any other suitable wearable device, and combinations thereof.

Further, system or device 1500 can be implemented in a server computer system, such as a dedicated server or on shared hardware that implements a cloud-based service 1570. System or device 1500 can be implemented in other electronic devices, such as a home electronic device 1580 that includes a refrigerator, a thermostat, a security camera, and other suitable home electronic devices. The interconnection of such devices can be referred to as the “Internet of Things” (IoT). System or device 1500 can also be implemented in various modes of transportation 1590, such as part of a vehicle's control system, guidance system, and/or entertainment system.

The systems and devices illustrated in FIG. 15 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the embodiments of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a device layer on the substrate, wherein the device layer comprises electronic devices; and
a metallization layer above the device layer, wherein the metallization layer comprises a capacitor structure comprising:
a first terminal trace;
a second terminal trace;
a switch; and
a plurality of capacitors, wherein a first terminal of a capacitor of the plurality of capacitors is coupled to the first terminal trace via the switch, a second terminal of the capacitor is coupled to the second terminal trace, and the first and second terminal traces are disposed along a same side of the plurality of capacitors.

2. The semiconductor device of claim 1, wherein:
a first terminal of another capacitor of the plurality of capacitors is coupled to the first terminal trace; and
a second terminal of the other capacitor is coupled to the second terminal trace.

3. The semiconductor device of claim 2, wherein:
the capacitor structure further comprises another switch; and
the first terminal of the other capacitor is coupled to the first terminal trace via the other switch.

4. The semiconductor device of claim 3, wherein the second terminal of the capacitor and the second terminal of the other capacitor are coupled to a same node.

5. The semiconductor device of claim 3, wherein:
a first terminal of a further capacitor of the plurality of capacitors is coupled to the first terminal trace via the other switch; and
a second terminal of the further capacitor is coupled to the second terminal trace.

6. The semiconductor device of claim 2, wherein:
the capacitor structure further comprises another switch; and
the second terminal of the other capacitor is coupled to the second terminal trace via the other switch.

7. The semiconductor device of claim 1, wherein:
the first and second terminal traces are arranged to be substantially parallel to one another.

8. The semiconductor device of claim 1, further comprising another metallization layer above the metallization layer, wherein:
the other metallization layer comprises an inductor that at least partially overlaps with the capacitor; and
the first and second terminal traces are disposed on a same side of the plurality of capacitors to mitigate eddy currents induced by magnetic fields from the inductor.

9. A semiconductor structure, comprising:
a substrate;
a device layer on the substrate, wherein the device layer comprises electronic devices; and
a metallization layer above the device layer, wherein the metallization layer comprises a capacitor structure comprising:
a first terminal trace;
a second terminal trace substantially parallel to the first terminal trace;
a switch; and
a first capacitor with a first terminal coupled to the first terminal trace via the switch and a second terminal coupled to the second terminal trace; and
a second capacitor coupled to the first and second terminal traces, wherein the first and second terminal traces are disposed between the first capacitor and the second capacitor.

10. The semiconductor structure of claim 9, wherein:
the capacitor structure further comprises another switch; and
the first terminal of the second capacitor is coupled to the first terminal trace via the other switch.

11. The semiconductor structure of claim 10, wherein the second terminal of the first capacitor and the second terminal of the second capacitor are coupled to a same node.

12. The semiconductor structure of claim 10, wherein the capacitor structure further comprises a third capacitor with a first terminal coupled to the first terminal trace via the other switch and a second terminal coupled to the second terminal trace.

13. The semiconductor structure of claim 9, wherein:
the capacitor structure comprises another switch; and
the second terminal of the second capacitor is coupled to the second terminal trace via the other switch.

14. The semiconductor structure of claim 9, further comprising another metallization layer above the metallization layer, wherein:
the other metallization layer comprises an inductor that at least partially overlaps with at least one of the first capacitor and the second capacitor; and
the first and second terminal traces are disposed between the first and second capacitors to mitigate eddy currents induced by magnetic fields from the inductor.

15. A method, comprising:
forming, on a substrate, a device layer comprising electronic devices; and
forming, in a metallization layer above the device layer, a capacitor structure comprising a switch, a first terminal trace, a second terminal trace, and a plurality of capacitors, wherein forming the capacitor structure comprises:
coupling a first terminal of a capacitor of the plurality of capacitors to a first end of the switch;
coupling a second end of the switch to the first terminal trace;
coupling a second terminal of the capacitor to the second interconnect structure; and
routing the first and second terminal traces along a same side of the plurality of capacitors.

16. The method of claim 15, wherein the capacitor structure comprises another switch and forming the capacitor structure further comprises:
coupling a first terminal of another capacitor of the plurality of capacitors to a first end of the other switch;
coupling a second end of the other switch to the first terminal trace; and
coupling a second terminal of the other capacitor to the second terminal trace.

17. The method of claim 16, wherein:
coupling the second terminal of the capacitor to the second terminal trace comprises coupling the second terminal of the capacitor to a node that is coupled to the second terminal trace; and
coupling the second terminal of the other capacitor to the second terminal trace comprises coupling the second terminal trace of the other capacitor to the node.

18. The method of claim 16, wherein forming the capacitor structure further comprises:
coupling a first terminal of a further capacitor of the plurality of capacitors to the first end of the other switch; and
coupling a second terminal of the further capacitor to the second terminal trace.

19. The method of claim 15, wherein forming the capacitor structure further comprises:
coupling a first terminal of another capacitor of the plurality of capacitors to the first terminal trace;
coupling a second terminal of the other capacitor to a second end of the other switch; and
coupling the second end of the other switch to the second terminal trace.

20. The method of claim 15, further comprising:
forming, in another metallization layer above the metallization layer, an inductor that at least partially overlaps with the capacitor.
